(19) United States
(12) Patent Application Publication
(10) Pub. No.: US 2024/0250037 A1
(43) Pub. Date: Jul. 25, 2024

(54) DISPLAY DEVICE

(71) Applicant: Samsung Display Co., LTD., Yongin-si (KR)

(72) Inventors: Gana KIM, Yongin-si (KR); Jangyeol YOON, Yongin-si (KR)

(21) Appl. No.: 18/416,560

(22) Filed: Jan. 18, 2024

(30) Foreign Application Priority Data
Jan. 20, 2023 (KR) 10-2023-0009029

(51) Int. Cl. H01L 23/538; H01L 23/00; H01L 25/13; H10K 59/82

(52) U.S. Cl. CPC H01L 23/5387; H01L 23/5385; H01L 24/08; H01L 25/13; H10K 59/82; H01L 2224/08225

(57) ABSTRACT

A display device includes: a display panel including light-emitting elements, a circuit board, and a flexible film electrically connected to the display panel and the circuit board. The flexible film includes: a first portion in which a plurality of first pads electrically connected to the display panel is arranged, a second portion in which a plurality of second pads electrically connected to the circuit board is arranged, and a third portion between the first portion and the second portion. The first portion defines a first cutout pattern therein and between two first pads adjacent to each other among the plurality of first pads, and the first cutout pattern extends to a first edge of the first portion in the flexible film.

This application claims priority to Korean Patent Application No. 10-2023-0009029, filed on Jan. 20, 2023, and all the benefits accruing therefrom under 35 U.S.C. § 119, the content of which in its entirety is herein incorporated by reference.

### BACKGROUND

### 1. Field

One or more embodiments relate to a display device, and more particularly, to a stretchable display device.

### 2. Description of the Related Art

As a display device that displays electrical signals visually has developed, various display devices having excellent characteristics such as reduction in thickness, weight, and power consumption have been introduced. Foldable, rollable, or flexible display devices have been under research and development. Furthermore, a stretchable display device capable of being transformed into various shapes has been actively under research and development.

### SUMMARY

One or more embodiments include a display device, in which an area other than a display area in which an image is displayed, for example, an area in which an image is not displayed, is stretchable. However, the above problems are merely examples, and the problems to be solved by the disclosure are not limited to the problems described above.

Additional aspects will be set forth in part in the description which follows and, in part, will be apparent from the description, or may be learned by practice of the presented embodiments of the disclosure.

According to one or more embodiments, a display device includes: a display panel including light-emitting elements, a circuit board, and a flexible film electrically connected to the display panel and the circuit board. The flexible film includes: a first portion in which a plurality of first pads electrically connected to the display panel is arranged, a second portion in which a plurality of second pads electrically connected to the circuit board is arranged, and a third portion between the first portion and the second portion. The first portion defines a first cutout pattern therein and between two first pads adjacent to each other among the plurality of first pads, and the first cutout pattern extends to a first edge of the first portion of the flexible film.

An elongation rate of the first portion may be greater than an elongation rate of the third portion.

The display panel may include pads corresponding to the plurality of first pads of the flexible film, and an elongation rate of one side-end portion of the display panel may be equal to or greater than an elongation rate of the first portion.

One side-end portion of the display panel may define a cutout pattern therein and overlapping the first cutout pattern of the flexible film in a plan view, and the cutout pattern of the display panel may extend to an edge of the display panel.

An elongation rate of the second portion may be greater than an elongation rate of the third portion. The first cutout pattern may include a first edge and a second edge between the two first pads adjacent to each other, and the first edge and the second edge of the first cutout pattern may each be uneven.

The second portion of the flexible film may define a second cutout pattern therein and between two second pads adjacent to each other among the plurality of second pads.

The second cutout pattern may extend to a second edge of the second portion of the flexible film.

The display device may further include: an integrated circuit (“IC”) chip on the third portion of the flexible film, a first line configured to electrically connect at least one of the plurality of first pads to the IC chip, and a second line configured to electrically connect at least one of the plurality of second pads to the IC chip.

At least one of the first line or the second line may include a portion extending in a serpentine type or may define a plurality of holes therein.

According to one or more embodiments, a display device includes: a display panel including light-emitting elements, a circuit board, and a flexible film electrically connected to the display panel and the circuit board. The flexible film includes: a first portion in which a plurality of first pads electrically connected to the display panel is arranged, a second portion in which a plurality of second pads electrically connected to the circuit board is arranged, and a third portion between the first portion and the second portion. The first portion defines a first groove pattern that is concave in a thickness direction of the flexible film and between two first pads adjacent to each other among the plurality of first pads.

An elongation rate of the first portion may be greater than an elongation rate of the third portion.

The first groove pattern may include a first portion having a first depth and a second portion having a second depth that is less than the first depth.

The display panel may include pads corresponding to the plurality of first pads of the flexible film, and an elongation rate of one side-end portion of the display panel may be equal to or greater than an elongation rate of the first portion.

One side-end portion of the display panel may define a groove pattern therein and overlapping the first groove pattern of the flexible film in a plan view.

The first groove pattern of the flexible film may extend to a first edge of the first portion of the flexible film, and the groove pattern of the display panel may extend to an edge of the display panel.

An elongation rate of the second portion of the flexible film may be greater than an elongation rate of the third portion.

The second portion of the flexible film may define a second groove pattern therein and between two second pads adjacent to each other among the plurality of second pads and extending to a second edge of the second portion of the flexible film.

The display device may further include an integrated circuit (IC) chip on the third portion of the flexible film, a first line configured to electrically connect at least one of the plurality of first pads to the IC chip, and a second line configured to electrically connect at least one of the plurality of second pads to the IC chip.

At least one of the first line or the second line may include a portion extending in a serpentine type or may define a plurality of holes therein.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1A is a plan view of a display device according to an embodiment, and FIG. 1B is a cross-sectional view of the display device taken along line I-I′ of FIG. 1A;

FIG. 2A is a plan view illustrating a portion of a display area of a display device, for example, a portion II of FIG. 1A, according to an embodiment;

FIG. 2B is a plan view illustrating a case where the display device of FIG. 2A stretches;

FIG. 2C is a perspective view illustrating a portion of a display area of a display device, according to another embodiment;

FIG. 3 is an exploded plan view illustrating a display panel, a flexible film, and a circuit board of a display device, according to an embodiment;

FIG. 4 is a plan view schematically illustrating a flexible film included in a display device, according to another embodiment;

FIGS. 5A and 5B are enlarged plan views of first to third lines according to other embodiments, respectively;

FIGS. 6A to 6D are plan views illustrating a portion of a flexible film according to other embodiments, respectively;

FIG. 7 is an exploded plan view illustrating a display panel, a flexible film, and a circuit board of a display device, according to another embodiment;

FIGS. 8A and 8B are cross-sectional views of a display panel and a flexible film taken along line VIII-VIII′ of FIG. 1A, according to other embodiments, respectively; and

FIGS. 9 and 10 illustrate states in which a display device according to an embodiment is applied, respectively.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present description allows for various changes and numerous embodiments, certain embodiments will be illustrated in the drawings and described in detail in the written description. Effects and features of the disclosure, and methods of achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings. When describing embodiments with reference to the accompanying drawings, the same or corresponding elements are denoted by the same reference numerals.

It will be understood that although the terms “first,” “second,” etc. may be used herein to describe various elements, these elements should not be limited by these terms. These terms are only used to distinguish one element from another.

The singular forms as used herein are intended to include the plural forms as well unless the context clearly indicates otherwise.

It will be further understood that the terms “include” and/or “comprise” used herein specify the presence of stated features or elements, but do not preclude the presence or addition of one or more other features or elements.

It will be further understood that, when a layer, region, or element is referred to as being “on” another layer, region, or element, it may be directly or indirectly on the other layer, region, or element. That is, for example, intervening layers, regions, or elements may be present.

Also, sizes of elements in the drawings may be exaggerated or reduced for convenience of explanation. For example, because sizes and thicknesses of elements in the drawings are arbitrarily illustrated for convenience of explanation, the disclosure is not limited thereto.

When a certain embodiment may be implemented differently, a specific process order may be performed differently from the described order. For example, two consecutively described processes may be performed substantially at the same time or performed in an order opposite to the described order.

It will be further understood that, when layers, regions, or elements are referred to as being connected to each other, they may be directly connected to each other or indirectly connected to each other with intervening layers, regions, or elements therebetween. For example, when layers, regions, or elements are referred to as being electrically connected to each other, they may be directly electrically connected to each other or indirectly electrically connected to each other with intervening layers, regions, or elements therebetween.

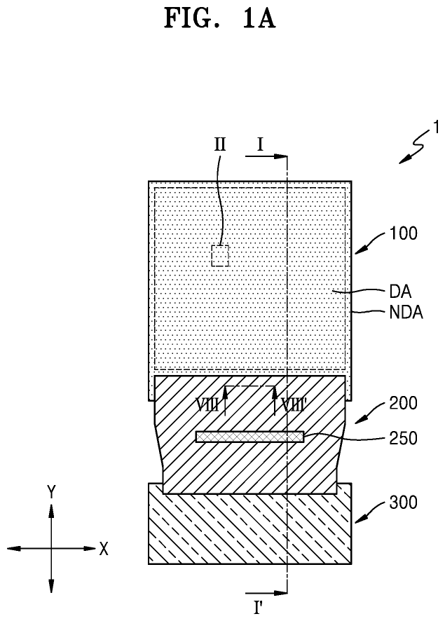

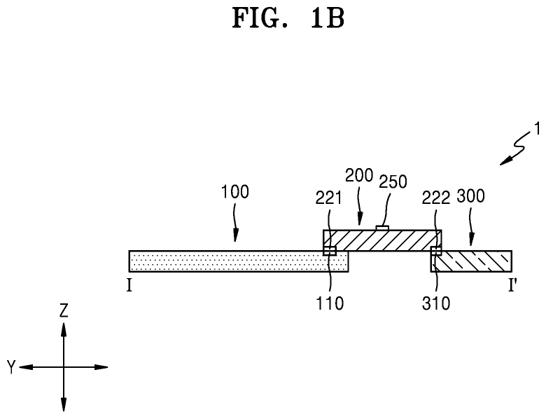

FIG. 1A is a plan view of a display device 1 according to an embodiment, and FIG. 1B is a cross-sectional view of the display device 1 taken along line I-I′ of FIG. 1A. As used herein, the “plan view” is a view from a thickness direction (Z direction) of the flexible film 200.

Referring to FIGS. 1A and 1B, the display device 1 may include a display area DA in which an image is displayed, and a peripheral area around the display area DA. The display area DA may be provided in a display panel 100. The display panel 100 may include a non-display area NDA surrounding the display area DA. A flexible film 200 may be disposed on a side-end portion of the display panel 100, for example, for example, on one side-end portion of the non-display area NDA.

The flexible film 200 may be configured to supply driving signals and power to the display panel 100. An integrated circuit (IC) chip 250 may be disposed on the flexible film 200. The IC chip 250 may include a driver configured to drive the display panel 100. A signal (e.g., a data signal, etc.) generated by the driver may be provided to the display panel 100.

One side of the flexible film 200 may be electrically connected to the display panel 100, and the other side of the flexible film 200 may be electrically connected to a circuit board 300. Referring to FIG. 1B, a pad 110 may be arranged in one side-end portion of the display panel 100. A first pad 221, which faces the pad 110 of the display panel 100 and is electrically connected to the pad 110, may be arranged in one side-end portion of the flexible film 200. A second pad 222 may be arranged in the other side-end portion of the flexible film 200. The second pad 222 of the flexible film 200 may be electrically connected to a pad 310 of the circuit board 300 facing the second pad 222. The circuit board 300 may include electronic chips configured to supply and control power or control the IC chip 250. The circuit board 300 may include a circuit board that is flexible like the display panel 100 or is less flexible than the flexible film 200.

Although FIG. 1A illustrates that the display device 1 includes one flexible film 200, the disclosure is not limited thereto. In another embodiment, a plurality of flexible films 200 may be spaced apart from each other on the side-end portion of the display panel 100, for example, on one side-end portion of the non-display area NDA.

Although FIG. 1A illustrates that the flexible film 200 is arranged in one of four side-end portions of the display panel 100, the disclosure is not limited thereto. In another embodiment, the flexible films 200 may be arranged in different side-end portions among the four side-end portions of the display panel 100.

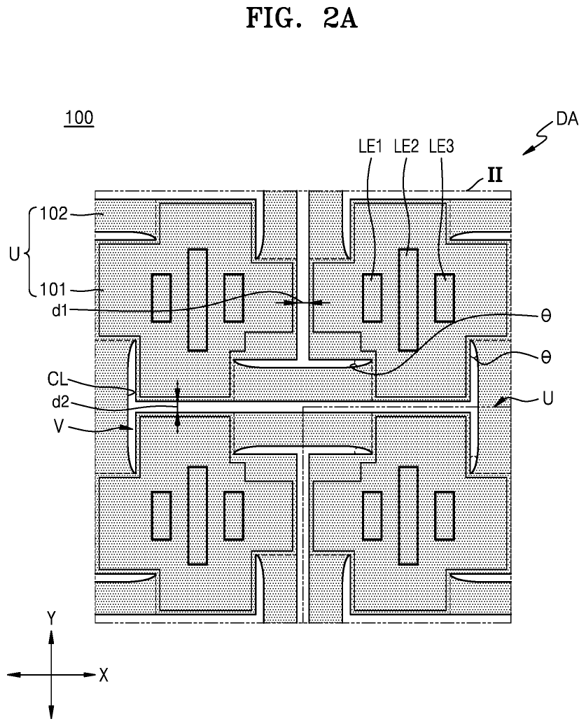

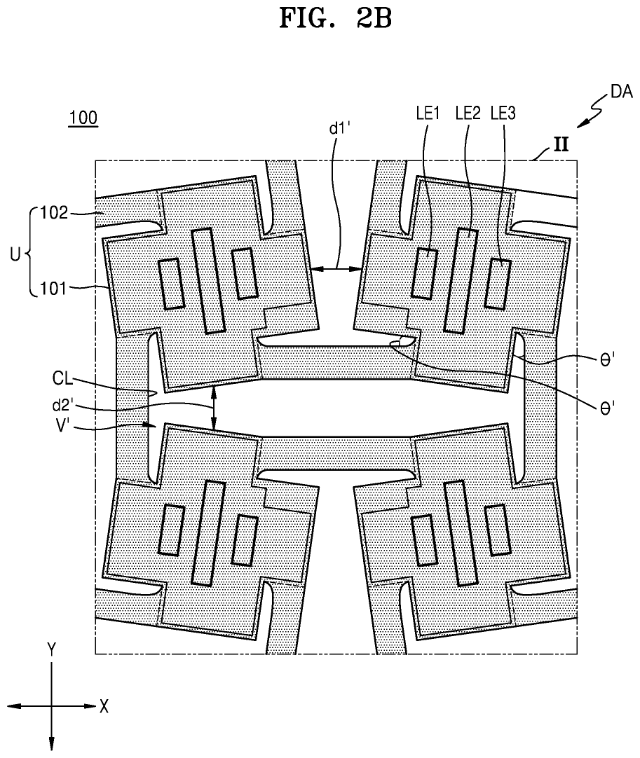

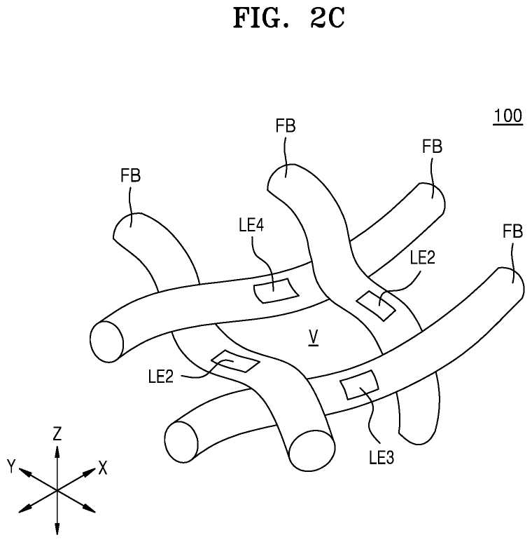

FIG. 2A is a plan view illustrating a portion of the display area DA of the display device, for example, a portion II of FIG. 1A, according to an embodiment, FIG. 2B is a plan view illustrating a case where the display device of FIG. 2A stretches, and FIG. 2C is a perspective view illustrating a portion of the display area DA of the display device, according to another embodiment.

Referring to FIG. 2A, the display area DA of the display device (see 1 of FIG. 1A) may include a structure in which basic units U are arranged. In other words, the display panel 100 may include an array of the basic units U.

The basic units U may each include an island portion 101 and connection portions 102 connected to the island portion 101. The basic units U may be repeatedly arranged in first and second directions, and two basic units U adjacent to each other may be symmetrical to each other. In an embodiment, for example, in FIG. 2A, two basic units U adjacent to each other in the horizontal direction (e.g., ±X directions) may be symmetrical with respect to a symmetry axis located therebetween and parallel to the vertical direction (e.g., ±Y directions). Similarly, in FIG. 2A, two basic units U adjacent to each other in the vertical direction (e.g., ±Y directions) may be symmetrical with respect to a symmetry axis located therebetween and parallel to the horizontal direction (e.g., ±X directions).

The basic units U may each include light-emitting elements, such as light-emitting diode. In an embodiment, for example, as illustrated in FIG. 2A, the basic units U may each include first to third light-emitting diodes LE1, LE2, and LE3 in the island portion 101.

The first to third light-emitting diodes LE1, LE2, and LE3 may each be an organic light-emitting diode including an organic emission layer or an inorganic light-emitting diode including an inorganic material. The inorganic light-emitting diode may include a

PN junction diode including inorganic semiconductor-based materials. When a voltage is applied to the PN junction diode in a forward direction, holes and electrons may be injected and recombined to generate energy, and the energy may be converted into light energy to emit light of a certain color. The inorganic light-emitting diode may have a length and/or a width of several to several hundred micrometers, or several to several hundred nanometers. In some embodiments, the first to third light-emitting diodes LE1, LE2, and LE3 may each include a quantum dot light-emitting diode including quantum dots. As described above, the emission layers of the first to third light-emitting diodes LE1, LE2, and LE3 may each include an organic material, an inorganic materials, or quantum dots, may each include an organic material and quantum dots, or may each include an inorganic material and quantum dots. The first to third light-emitting diodes LE1, LE2, and LE3 may each have a bar or rod shape. Alternatively, the first to third light-emitting diodes LE1, LE2, and LE3 may each have various shapes. In an embodiment, for example, the first to third light-emitting diodes LE1, LE2, and LE3 may each have a polygonal planar shape, an elliptical planar shape, or a circular planar shape having a certain area.

The basic units U adjacent to each other may define separation areas V therebetween. In an embodiment, for example, the four basic units U illustrated in FIG. 2A may define the separation areas V therebetween, which are empty spaces surrounded by a closed curve CL. The separation areas V may be areas surrounded by closed curves CL including edges of the plurality of island portions 101 and edges of a plurality of connection portions 102. The separation area V may be a type of through-hole passing through the display panel 100. When external force (e.g., bending force, folding force, pulling force, etc.) is applied to the display panel 100, the shape of the separation areas V change, and thus, stress occurring when the display panel 100 transforms may be easily reduced.

The edge of the island portion 101 and the edge of the connection portion 102 connected to the island portion 101 are spaced apart from each other and may have a certain angle θ therebetween. When external force pulling the display panel 100 is applied to the display panel 100, as illustrated in FIG. 2B, an angle θ′ between the edge of the island portion 101 and the edge of the connection portion 102 may increase (θ′>θ), the area or shape of the separation area V′ may be changed, and the position of the island portion 101 may also be changed.

FIG. 2B is a plan view illustrating that the display panel 100 is stretched by external force. When the above-described force is applied to the display panel 100, the island portions 101 may be rotated at a certain angle by a change in the angle θ′, an increase in the area of the separation area V′, and/or a change in shape. Due to the rotation of the island portions 101, distances between the island portions 101, for example, a first distance d1′ and a second distance d2′, may vary according to positions.

In another embodiment, the display panel 100 may have a fabric shape as illustrated in FIG. 2C. Referring to FIG. 2C, the first to third light-emitting diodes LE1, LE2, and LE3 may be woven in a fabric shape with a certain pattern. The first to third light-emitting diodes LE1, LE2, and LE3 may be disposed or embedded in fibers (e.g., polymer fibers FB). Because the polymer fibers FB are formed to have a fabric structure, the shape of the space of the separation area V between the polymer fibers FB may change when external force is applied thereto.

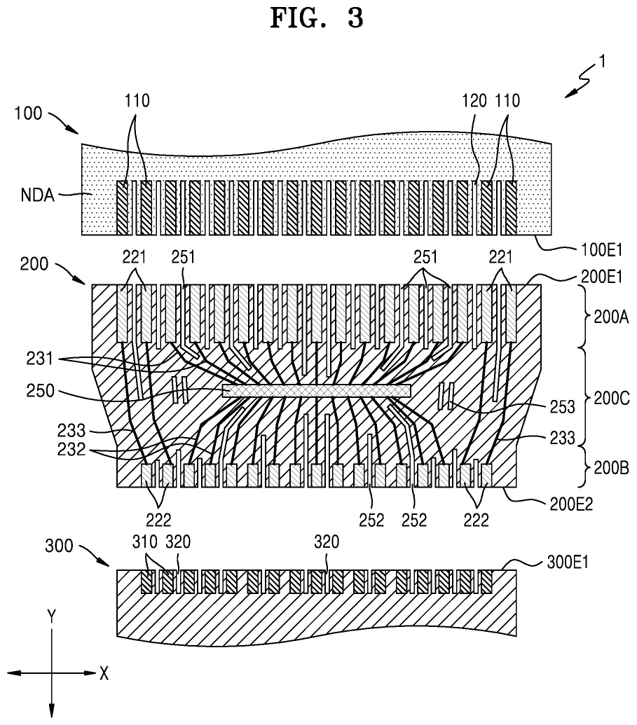

FIG. 3 is an exploded plan view illustrating a display panel 100, a flexible film 200, and a circuit board 300 of a display device 1, according to an embodiment. For convenience of explanation, the display panel 100 illustrated in FIG. 3 is a portion of a non-display area NDA.

The display panel 100 may include pads 110 arranged in the non-display area NDA. The pads 110 may be arranged in one side-end portion of the display panel 100. The pads 110 may each extend to an edge 100E1 of the display panel 100 in one direction (e.g., ±Y directions). The pads 110 may have a shape in which the width of the pads 110 in the arrangement direction (e.g., ±X directions) is less than the length of the pads 110 in a direction (i.e., the longitudinal direction of the pad 110, for example, ±Y directions) crossing the arrangement direction.

The display panel 100 may define cutout patterns 120 (an empty space) between two pads 110 adjacent to each other. The cutout patterns 120 may penetrate the display panel 100. The cutout patterns 120 may extend in the longitudinal direction (±Y directions) of the pads 110. In an embodiment, for example, the length of the cutout pattern 120 in the longitudinal direction may be greater than the width of the cutout pattern 120 in a latitudinal direction (±X directions) in a plan view. The cutout patterns 120 may each extend to the edge 100E1 of the display panel 100. In other words, the cutout pattern 120 may have a notch hole shape, one side of which is spatially connected to the outside, in a plan view. In an embodiment, one side-end portion of the display panel 100 may define a cutout pattern 120 therein and overlapping the first cutout pattern 251 of the flexible film 200 in a plan view

The flexible film 200 may include a first portion 200A, a second portion 200B opposite to the first portion 200A, and a third portion 200C between the first portion 200A and the second portion 200B. The first portion 200A and the second portion 200B may be spaced apart from each other on opposite sides with the third portion 200C therebetween.

As described above with reference to FIG. 1B, the first portion 200A of the flexible film 200 may overlap one side-end portion of the display panel 100 in a plan view and may be electrically connected to the display panel 100. As described above with reference to FIG. 1B, the second portion 200B of the flexible film 200 may overlap one side-end portion of the circuit board 300 in a plan view and may be electrically connected to the circuit board 300. The first pads 221 arranged in the first portion 200A of the flexible film 200 may correspond to the pads 110 of the display panel 100 one to one, and the second pads 222 arranged in the second portion 200B of the flexible film 200 may correspond to pads 310 of the circuit board 300 one to one. As described above with reference to FIG. 1B, the first pads 221 of the flexible film 200 may be electrically connected to the pads 110 of the display panel 100 by facing the pads 110 of the display panel 100, and the second pads 222 of the flexible film 200 may be electrically connected to the pads 310 of the circuit board 300 by facing the pads 310 of the circuit board 300.

The first pads 221 of the flexible film 200 may be spaced apart from each other in one direction (e.g., ±X directions) in the first portion 200A. The first pads 221 may be arranged close to a first edge 200E1 of the flexible film 200. In an embodiment, for example, the first pads 221 may each extend to the first edge 200E1 of the flexible film 200. The first pads 221 may each have a shape in which the length in the ±Y directions is greater than the width in the ±X directions.

The second pads 222 of the flexible film 200 may be spaced apart from each other in one direction (e.g., ±X directions) in the second portion 200B. The second pads 222 may be arranged close to a second edge 200E2 of the flexible film 200. In an embodiment, for example, the second pads 222 may each extend to the second edge 200E2 of the flexible film 200. The second pads 222 may each have a shape in which the length in the ±Y directions is greater than the width in the ±X directions. The first edge 200E1 and the second edge 200E2 may be located in opposite sides of the flexible film 200 in the Y direction.

The first pads 221 and the second pads 222 may be electrically connected to electrical lines, respectively. In an embodiment, for example, some first pads 221 may be electrically connected to first lines 231 and may be electrically connected to the IC chip 250 arranged in the third portion 200C through the first lines 231. Some second pads 222 may be electrically connected to second lines 232 and may be electrically connected to the IC chip 250 arranged in the third portion 200C through second lines 232. Some first pads 221, for example, the first pads 221 arranged in a relatively outer portion of the second portion 200B in the arrangement direction (e.g., ±X directions) of the first pads 221, may be electrically connected to some second pads 222 through third lines 233. The second pads 222 electrically connected to the third lines 233 may be arranged in a relatively outer portion of the second portion 200B in the arrangement direction (e.g., ±X directions) of the second pads 222.

The first portion 200A may define a first cutout pattern 251 (i.e., an empty space) between two first pads 221 adjacent to each other. The first cutout pattern 251 may penetrate the flexible film 200. The first portion 200A may define first cutout patterns 251 therein and spaced apart from each other. The first cutout patterns 251 may each have a shape in which the length in the ±Y directions is greater than the width in the ±X directions. The first cutout patterns 251 may extend to the first edge 200E1 of the first portion 200A in the flexible film 200.

In some embodiments, the length of each of the first cutout patterns 251 may be greater than the length of each of the first pads 221 in the ±Y directions. As illustrated in FIG. 3, some first cutout patterns 251 may each have a straight-line shape, and other first cutout patterns 251 may each be bent to have a certain angle (e.g., an obtuse angle) with respect to a direction from the first portion 200A to the third portion 200C (i.e., ±Y directions). At least one of the first cutout patterns 251 may extend to the third portion 200C.

The second portion 200B may define a second cutout pattern 252 (i.e., an empty space) between two second pads 222 adjacent to each other. The second cutout pattern 252 may penetrate the flexible film 200. The second portion 200B may define second cutout patterns 252 therein and spaced apart from each other. The second cutout patterns 252 may each have a shape in which the length in the ±Y directions is greater than the width in the ±X directions. The second cutout patterns 252 may extend to a second edge 200E2 of the second portion 200B in the flexible film 200.

In some embodiments, the length of each of the second cutout patterns 252 may be greater than the length of each of the second pads 222 in the ±Y directions. As illustrated in FIG. 3, some second cutout patterns 252 may each have a straight-line shape, and other second cutout patterns 252 may each be bent to have a certain angle (e.g., an obtuse angle) with respect to a direction from the second portion 200B to the third portion 200C (i.e., ±Y directions). At least one of the second cutout patterns 252 may extend to the third portion 200C.

The third portion 200C may include a portion of the first cutout pattern 251 extending from the first portion 200A, a portion of the second cutout pattern 252 extending from the second portion 200B, and/or an auxiliary cutout pattern 253 defined in the third portion 200C. Unlike the first cutout pattern 251 or the second cutout pattern 252 having an opening shape with one side open (or a notch type), the auxiliary cutout pattern 253 may have an opening shape with a closed curve shape in a plan view.

The ratio of expansion and contraction (in other words, “elongation rate”) of the first portion 200A including the first cutout patterns 251 and the ratio of expansion and contraction of the second portion 200B including the second cutout patterns 252 may each be greater than the ratio of expansion and contraction of the third portion 200C. The ratio of expansion and contraction of the second portion 200B of the flexible film 200 may be equal to or less than the ratio of expansion and contraction of the first portion 200A of the flexible film 200. The number and/or length of the second cutout patterns 252 of the second portion 200B may be equal to or less than the number and/or length of the first cutout patterns 251 of the first portion 200A. In an embodiment, FIG. 3 illustrates that the number and/or length of the second cutout patterns 252 of the second portion 200B is less than the number and/or length of the first cutout patterns 251 of the first portion 200.

The ratio of expansion and contraction of the first portion 200A of the flexible film 200 may be substantially equal to or less than the ratio of expansion and contraction of the display panel 100 (e.g., the ratio of expansion and contraction of the non-display area NDA of the display panel 100 on which the pads 110 are arranged). As described above, because the flexible film 200 has different ratios of expansion and contraction for each portion, the flexible film 200 may stretch or contract together with the display panel 100 while maintaining the strength around the IC chip 250.

The circuit board 300 may include pads 310 on one side thereof. The pads 310 may be arranged in one side-end portion of the circuit board 300. The pads 310 may each extend to an edge 300E1 of the circuit board 300 in one direction (e.g., ±Y directions). The pads 310 may each have a shape in which the length in the ±Y directions is greater than the width in the ±X directions.

The circuit board 300 may define cutout patterns 320 (i.e., an empty space) between two pads 310 adjacent to each other. The cutout pattern 320 may penetrate the circuit board 300. The cutout patterns 320 may extend in the longitudinal direction (i.e., the ±Y directions) of the pads 310. In an embodiment, for example, the length of the cutout pattern 320 in the ±Y directions may be greater than the width of the cutout pattern 320 in the ±X directions in a plan view. The cutout patterns 320 may each extend to the edge 300E1 of the circuit board 300. In other words, the cutout pattern 320 may have a notch hole shape, one side of which is spatially connected to the outside, in a plan view.

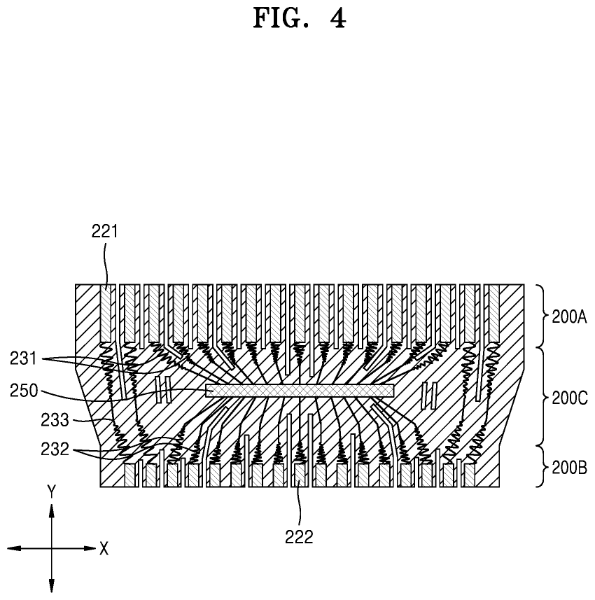

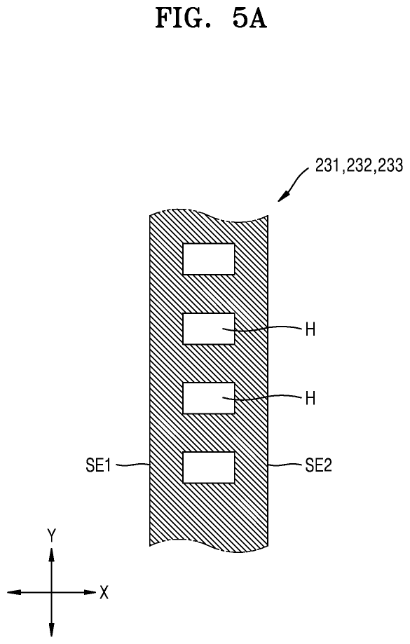

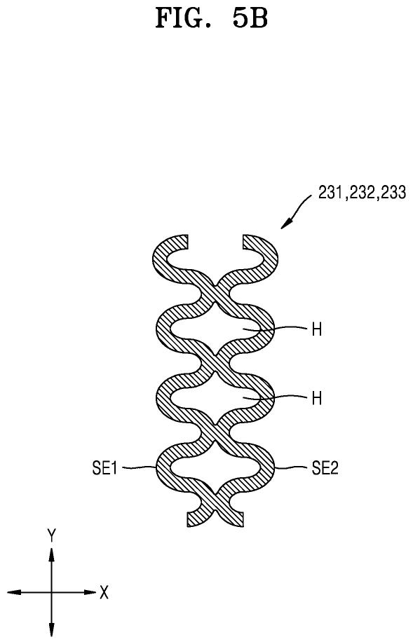

FIG. 4 is a plan view schematically illustrating a flexible film 200 included in a display device, according to another embodiment, and FIGS. 5A and 5B are enlarged plan views of first to third lines 231, 232, and 233 according to other embodiments, respectively.

The flexible film 200 illustrated in FIG. 4 includes substantially the same structure as the flexible film 200 described above with reference to FIG. 3, except for the shape of the first to third lines 231, 232, and 233. Hereinafter, differences will be mainly described for convenience of explanation.

As some embodiments, the first to third lines 231, 232, and 233 may each be bent at least once, as illustrated in FIG. 3, but opposite sides of the bent portion may have a straight-line shape. As another example, the first to third lines 231, 232, and 233 may each include a portion extending in a serpentine type, as illustrated in FIG. 4. In an embodiment, for example, the first line 231 and the second line 232 may each include a serpentine portion having approximate “S” shapes. The third line 233 may also include a serpentine portion having approximate “S” shapes.

FIG. 4 illustrates that a portion of the first line 231 adjacent to the first pad 221 extends in a serpentine type, and another portion of the first line 231 adjacent to the IC chip 250 extends in a straight-line type. In addition, FIG. 4 illustrates that a portion of the second line 232 adjacent to the second pad 222 extends in a serpentine type, and another portion of the second line 232 adjacent to the IC chip 250 extends in a straight-line type. In another embodiment, the first line 231 and the second line 232 may each have a serpentine shape as a whole.

Although FIG. 4 illustrates that a portion of the third line 233 adjacent to the first pad 221 and a portion of the third line 233 adjacent to the second pad 222 each extend in a serpentine type and are linear therebetween, the disclosure is not limited thereto. In another embodiment, the third line 233 may have a serpentine shape as a whole.

Although FIG. 4 illustrates a case in which the first to third lines 231, 232, and 233 each include a portion extending in a serpentine type, the disclosure is not limited thereto. In another embodiment, as illustrated in FIGS. 5A and 5B, the first to third lines 231, 232, and 233 may each include holes.

As illustrated in FIGS. 5A and 5B, the first to third lines 231, 232, and 233 each define holes H therein and spaced apart from each other in the longitudinal direction (e.g., ±Y directions) of the first to third lines 231, 232, and 233. In an embodiment, for example, as illustrated in FIG. 5A, the first to third lines 231, 232, and 233 may have a structure in which two edges SE1 and SE2 include substantially straight portions and holes H are between the two edges SE1 and SE2. Alternatively, as illustrated in FIG. 5B, the first to third lines 231, 232, and 233 may have a structure in which each of two edges SE1 and SE2 extend in a serpentine type to have approximate “S” shapes and holes H are between the two edges SE1 and SE2. As illustrated in FIG. 5A, the holes H may each have a polygonal shape such as a rectangular shape. As illustrated in FIG. 5B, the holes H may each have an irregular shape with a round contour line. Alternatively, although not illustrated, the holes H may each have various shapes such as a circular shape or an elliptical shape.

In the case of having a structure as illustrated in FIGS. 4, 5A, and 5B, when the flexible film 200 stretches or contracts, the first to third lines 231, 232, and 233 may freely stretch or contract in various directions.

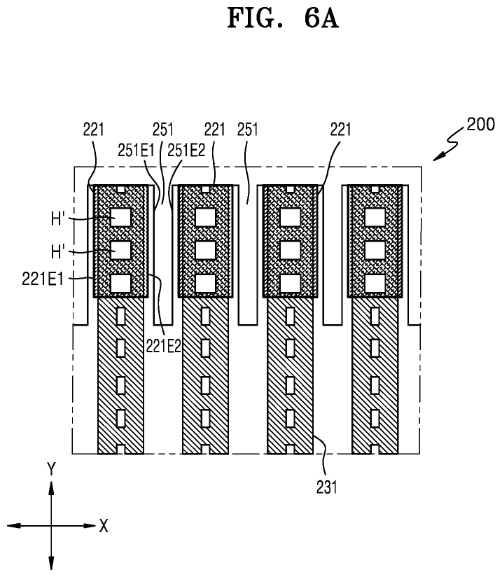

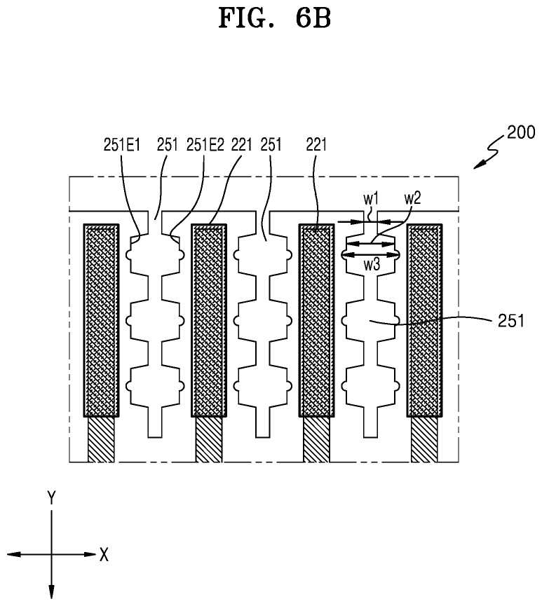

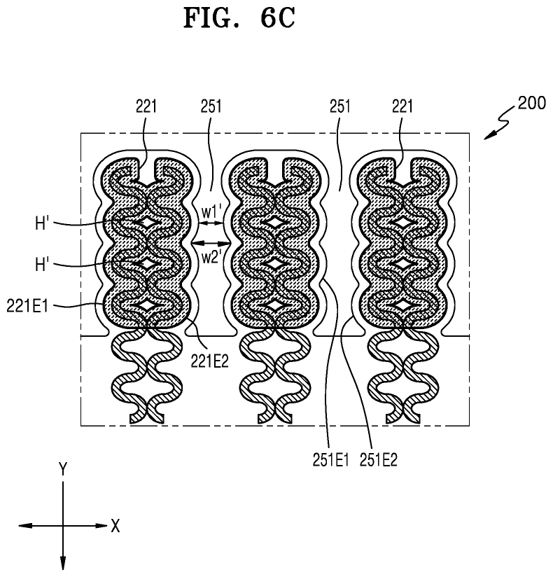

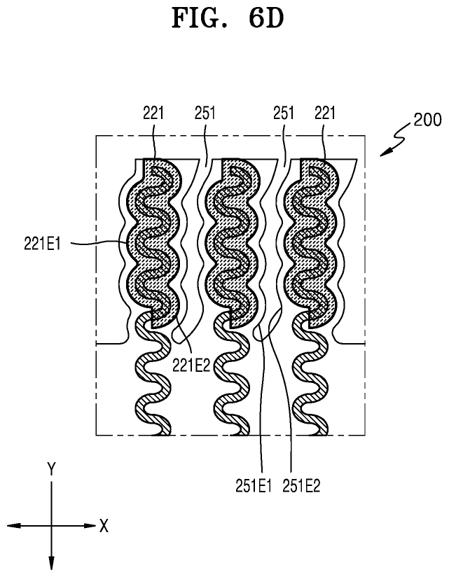

FIGS. 6A to 6D are plan views illustrating a portion of a flexible film 200, respectively, according to other embodiments. For convenience of explanation, FIGS. 6A to 6D illustrate the first pad 221 and the first line 231 arranged in the first portion 200A of the flexible film 200, but the second pad (see 222 of FIG. 3) and the second line (see 232 of FIG. 3) may also have substantially the same characteristics and structures as characteristics and structures of the first pad 221 and the first line 231 to be described with reference to FIGS. 6A to 6D.

Referring to FIG. 6A, the first pad 221 may be electrically connected to the first line 231 while overlapping the first line 231 in a plan view, and may define holes H′ therein. The first pad 221 may include holes H′ arranged in the longitudinal direction (e.g., ±Y directions) of the first pad 221. The holes H′ may be spatially separated or spaced apart from each other. Similar to the planar shape of the first pad 221, the first line 231 may have a planar shape as described above with reference to FIG. 5A, but the disclosure is not limited thereto. The shape of the first line 231 may be variously changed.

As described above with reference to FIG. 3, the first cutout pattern 251 between two first pads 221 adjacent to each other may have a shape with one end portion open. Although FIG. 6A illustrates that first and second edges 251E1 and 251E2 of the first cutout pattern 251 each have substantially a straight-line shape, the disclosure is not limited thereto.

In another embodiment, as illustrated in FIGS. 6B to 6D, the first and second edges 251E1 and 251E2 of the first cutout pattern 251 may be between two first pads 221 adjacent to each other and may each be uneven.

In an embodiment, for example, the first and second edges 251E1 and 251E2 of the first cutout pattern 251 may each be bent stepwise to have a stepped portion. As illustrated in FIG. 6B, the first cutout pattern 251 may have a structure in which a first width w1, a second width w2, a third width w3, and a second width w2 are repeated in the longitudinal direction (e.g., ±Y directions) of the first cutout pattern 251. The third width w3 in the ±X directions may be greater than the second width w2 in the ±X directions, and the second width w2 in the ±X directions may be greater than the first width w1 in the ±X directions.

In an embodiment, for example, as illustrated in FIG. 6C, the first cutout pattern 251 may have a structure in which a first width w1′ and a second width w2′ are repeated in the longitudinal direction (e.g., ±Y directions) of the first cutout pattern 251. The second width w2′ in the ±X directions may be greater than the first width w1′ in the ±X directions. The first and second edges 251E1 and 251E2 of the first cutout pattern 251 may each include a curve. Alternatively, as illustrated in FIG. 6D, the first and second edges 251E1 and 251E2 of the first cutout pattern 251 may each include a curve, but the width of the first cutout pattern 251 may be substantially constant. The first and second edges 251E1 and 251E2 of the first cutout pattern 251 may be substantially parallel to each other.

Although FIG. 6A illustrates that first and second edges 221E1 and 221E2 of the first pad 221 are substantially straight in a plan view and the first pad 221 has a ladder shape, the disclosure is not limited thereto.

In another embodiment, as illustrated in FIGS. 6C and 6D, the first and second edges 221E1 and 221E2 of the first pad 221 may each include a curve. As illustrated in FIG. 6C, the first pad 221 may define holes H′ therein and spaced apart from each other in the longitudinal direction (e.g., ±Y directions) of the first pad 221. The holes H′ may have a shape including a curve in a plan view. Alternatively, as illustrated in FIG. 6D, no holes may be included.

Because the first pad 221 and/or the first cutout pattern 251 includes the structure described above, damage to the first pad 221 may be effectively prevented when the flexible film (see 200 of FIG. 3) stretches or contracts without limitation in the stretching/contracting direction of the flexible film.

Although FIGS. 6A to 6D illustrate the first pad 221 and the first cutout pattern 251 of the first portion 200A in the flexible film 200, the planar shapes of the second pad (see 222 of FIG. 3) and the second cutout pattern 252 of the second portion 200B in the flexible film 200 may also be the same as described with reference to FIGS. 6A to 6D.

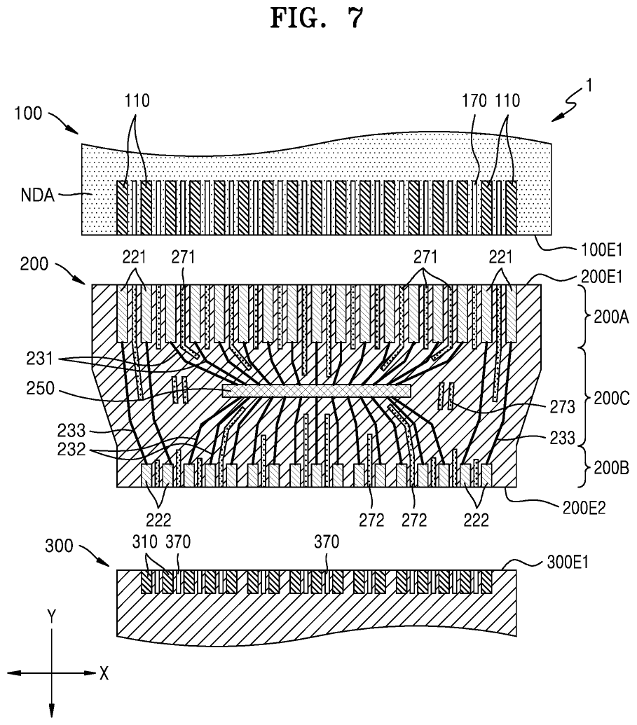

FIG. 7 is an exploded plan view illustrating a display panel 100, a flexible film 200, and a circuit board 300 of a display device 1, according to another embodiment. For convenience of explanation, the display panel 100 illustrated in FIG. 7 is a portion of a non-display area NDA.

The display panel 100 may include pads 110 arranged in the non-display area NDA. The pads 110 may each have a shape in which the length in the ±Y directions is greater than the width in the ±X directions. The pads 110 may each extend to an edge 100E1 of the display panel 100 in one direction (e.g., ±Y directions).

The display panel 100 may define groove patterns 170 therein and between two pads 110 adjacent to each other. The groove patterns 170 may each extend in the longitudinal direction of the pads 110. In an embodiment, for example, the length of the groove patterns 170 ±Y directions may be greater than the width of the groove patterns 170 ±X directions in a plan view. The groove pattern 170 may extend to the edge 100E1 of the display panel 100. In other words, one side of the groove pattern 170 may be spatially connected to the outside in a plan view. In an embodiment, one side-end portion of the display panel 100 may define a groove pattern 271 therein and overlapping the first groove pattern 271 of the flexible film 200 in a plan view.

The flexible film 200 may include a first portion 200A, a second portion 200B opposite to the first portion 200A, and a third portion 200C between the first portion 200A and the second portion 200B. The first portion 200A and the second portion 200B may be opposite to each other with the third portion 200C therebetween.

The first portion 200A of the flexible film 200 may include first pads 221, and the second portion 200B may include second pads 222. As described above with reference to FIG. 1B, the first pads 221 of the flexible film 200 may be electrically connected to the pads 110 of the display panel 100 by facing the pads 110 of the display panel 100. As described above with reference to FIG. 1B, the second pads 222 of the flexible film 200 may be electrically connected to the pads 310 of the circuit board 300 by facing the pads 310 of the circuit board 300. Because the first pads 221 and the second pads 222 are the same as described above with reference to FIG. 3, the same description as provided above is equally applied to the first pads 221 and the second pads 222.

The first pads 221 and the second pads 222 may be electrically connected to electrical lines, respectively. In an embodiment, for example, some first pads 221 may be electrically connected to first lines 231 and may be electrically connected to the IC chip 250 arranged in the third portion 200C through the first lines 231. Some second pads 222 may be electrically connected to second lines 232 and may be electrically connected to the IC chip 250 arranged in the third portion 200C through the second lines 232. Some first pads 221, for example, the first pads 221 arranged in a relatively outer portion of the second portion 200B in the arrangement direction (e.g., ±X directions) of the first pads 221, may be electrically connected to some second pads 222 through the third lines 233. The second pads 222 electrically connected to the third lines 233 may be arranged in a relatively outer portion of the second portion 200B in the arrangement direction (e.g., ±X directions) of the second pads 222.

The first portion 200A may define a first groove pattern 271 therein and between two first pads 221 adjacent to each other. The first portion 200A may include first groove patterns 271 spaced apart from each other in the arrangement direction (i.e., ±X directions). The first groove patterns 271 may each have a shape in which the length in the ±Y directions is greater than the width in the ±X directions in a plan view. The first groove pattern 271 of the flexible film 200 may extend to a first edge 200E1 of the first portion 200A in the flexible film 200.

In some embodiments, the length of each of the first groove patterns 271 may be greater than the length of each of the first pads 221. Some first groove patterns 271 may each have a straight-line shape, and other first groove patterns 271 may each be bent to have a certain angle (e.g., an obtuse angle) between the first portion 200A and the third portion 200C. At least one of the first groove patterns 271 may extend to the third portion 200C.

The second portion 200B may define a second groove pattern 272 therein and between two second pads 222 adjacent to each other. The second portion 200B may include second groove patterns 272 spaced apart from each other in the arrangement direction (i.e., ±X directions). The second groove patterns 272 may each have a shape in which the length in the ±Y directions is greater than the width in the ±X directions. The second groove patterns 272 may extend to a second edge 200E2 of the second portion 200B in the flexible film 200.

In some embodiments, the length of each of the second groove patterns 272 in the ±Y directions may be greater than the length of each of the second pads 222. As illustrated in FIG. 7, some second groove patterns 272 may each have a straight-line shape, and other second groove patterns 272 may each be bent to have a certain angle (e.g., an obtuse angle) between the second portion 200B and the third portion 200C. At least one of the second groove patterns 272 may extend to the third portion 200C.

The third portion 200C may include a portion of the first groove pattern 271 extending from the first portion 200A and/or a portion of the second groove pattern 272 extending from the second portion 200B.

Due to the first groove patterns 271 and the second groove patterns 272 having the structures and characteristics described above, the ratio of expansion and contraction (in other words, “elongation rate”) of the first portion 200A and the second portion 200B of the flexible film 200 may each be greater than the ratio of expansion and contraction of the third portion 200C. The ratio of expansion and contraction of the second portion 200B of the flexible film 200 may be equal to or less than the ratio of expansion and contraction of the first portion 200A of the flexible film 200. The number and/or length of the second groove patterns 272 of the second portion 200B may be equal to or less than the number and/or length of the first groove patterns 271 of the first portion 200A. In an embodiment, FIG. 7 illustrates that the number and/or length of the second groove patterns 272 of the second portion 200B is less than the number and/or length of the first groove patterns 271 of the first portion 200A.

The ratio of expansion and contraction of the first portion 200A of the flexible film 200 may be substantially equal to or less than the ratio of expansion and contraction of the display panel 100 (e.g., the ratio of expansion and contraction of the non-display area NDA of the display panel 100 on which the pads 110 are arranged), and may be greater than the ratio of expansion and contraction of the third portion 200C. Because the flexible film 200 has different ratios of expansion and contraction for each portion, the flexible film 200 may stretch or contract together with the display panel 100 while maintaining the strength around the IC chip 250, and a signal provided from the IC chip 250 may be transmitted to the display panel 100 without interruption.

The circuit board 300 may include pads 310 on one side thereof. The pads 310 may be arranged in one side-end portion of the circuit board 300. The pads 310 may each extend to an edge 300E1 of the circuit board 300 in one direction (e.g., ±Y directions). The pads 310 may each have a shape in which the length in the ±Y directions is greater than the width in the ±X directions.

The circuit board 300 may define groove patterns 370 therein and between two pads 310 adjacent to each other. The groove patterns 370 may each extend in the longitudinal direction (±Y directions) of the pads 310. In an embodiment, for example, the length of the groove patterns 370 in the ±Y directions may be greater than the width of the groove patterns 370 in the ±X directions in a plan view. The groove patterns 370 may each extend to the edge 300E1 of the circuit board 300.

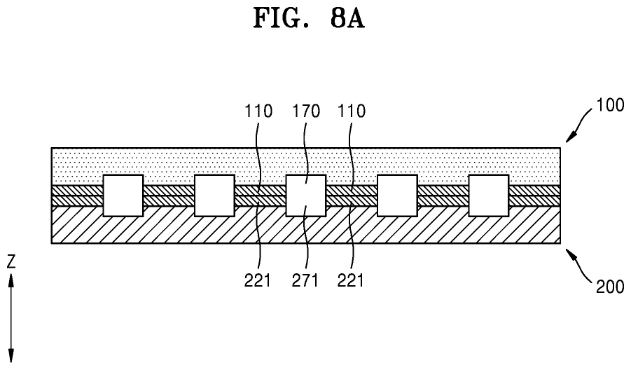

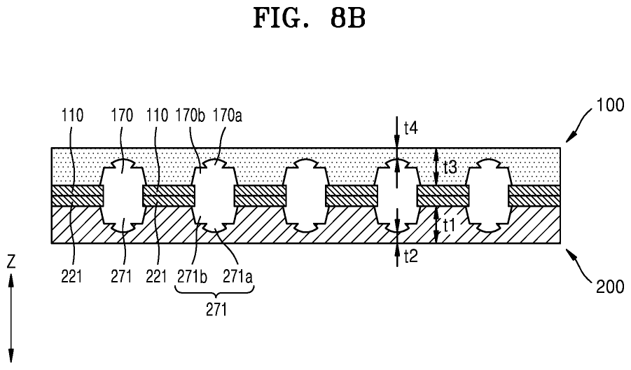

FIGS. 8A and 8B are cross-sectional views of a display panel 100 and a flexible film 200, respectively, according to other embodiments. FIGS. 8A and 8B illustrate a state in which the display panel 100 and the flexible film 200 are electrically connected to each other, and may correspond to a cross-section taken along line VIII-VIII′ of FIG. 1A. Referring to FIG. 8A, the display panel 100 may include concave groove patterns 170 in the thickness direction (e.g., ±Z directions). As described above with reference to FIG. 7, the groove pattern 170 may be between two pads 110 adjacent to each other. The groove pattern 170 may be concave to have a certain depth in the thickness direction (e.g., ±Z directions) of the display panel 100. The pads 110 may be located at portions that are relatively convex with respect to the groove pattern 170.

The flexible film 200 may include a first groove pattern 271 that is concave in the thickness direction (e.g., ±Z directions). As described above with reference to FIG. 7, the first groove pattern 271 may be between two first pads 221 adjacent to each other. The first groove pattern 271 may be concave to have a certain depth in the thickness direction (e.g., ±Z directions) of the flexible film 200. The first pads 221 may be located at portions that are relatively convex in the thickness direction (e.g., ±Z directions) with respect to the first groove pattern 271.

In the display panel 100 and the flexible film 200, the pad 110 of the display panel 100 and the first pad 221 of the flexible film 200 may be arranged to face each other. As illustrated in FIGS. 8A and 8B, the pad 110 of the display panel 100 and the first pad 221 of the flexible film 200 may be in direct contact with each other. Alternatively, the pad 110 of the display panel 100 and the first pad 221 of the flexible film 200 may be electrically connected to each other with a conductive material layer therebetween. The groove pattern 170 of the display panel 100 and the first groove pattern 271 of the flexible film 200 may be arranged to face each other. Because a portion of the display panel 100 corresponding to the groove pattern 170 and a portion of the flexible film 200 corresponding to the first groove pattern 271 have a relatively small thickness, the display device 1 may be easily transformed when the display device 1 stretches or contracts.

Although FIG. 8A illustrates that the groove pattern 170 of the display panel 100 and the first groove pattern 271 of the flexible film 200 have a certain depth, the disclosure is not limited thereto. In another embodiment, as illustrated in FIG. 8B, the groove pattern 170 of the display panel 100 and/or the first groove pattern 271 of the flexible film 200 may include portions having different depths from each other.

As illustrated in FIG. 8B, the groove pattern 170 of the display panel 100 may include a first portion 170a having a first depth and a second portion 170b having a second depth that is less than the first depth in the thickness direction (Z direction). In some embodiments, in a cross-sectional view, the groove pattern 170 of the display panel 100 may have a structure in which the second portions 170b are arranged on opposite sides with the first portion 170a therebetween.

The first groove pattern 271 of the flexible film 200 may include a first portion 271a having a first depth and a second portion 271b having a second depth that is less than the first depth in the thickness direction (Z direction). In some embodiments, in a cross-sectional view, the first groove pattern 271 of the flexible film 200 may have a structure in which the second portions 271b are arranged on opposite sides with the first portion 271a therebetween.

As illustrated in FIGS. 8A and 8B, a first thickness t1 of the flexible film 200 corresponding to the first pad 221 in the thickness direction (Z direction) may be greater than a second thickness t2 of the flexible film 200 corresponding to the first groove pattern 271. Similarly, a third thickness t3 of the display panel 100 corresponding to the pad 110 may be greater than a fourth thickness t4 of the display panel 100 corresponding to the groove pattern 170 in the thickness direction (Z direction).

Although the groove pattern 170 of the display panel 100 and the first groove pattern 271 of the flexible film 200 have been described above with reference to FIGS. 8A and 8B, the disclosure is not limited thereto. A groove pattern 370 of a circuit board 300 may have the same structure as the groove pattern 170 of the display panel 100 described above with reference to FIG. 8A or 8B, and a second groove pattern 272 of the flexible film 200 may have the same structure as the first groove pattern 271 of the flexible film 200 described above with reference to FIG. 8A or 8B.

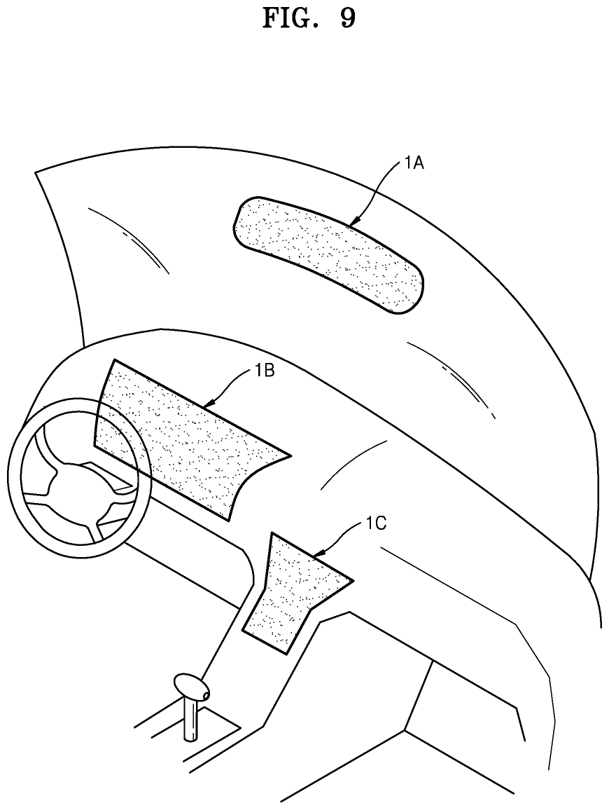

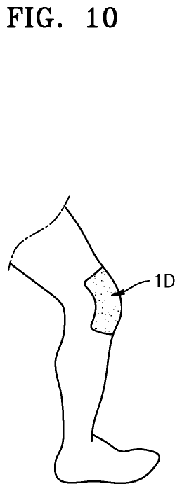

FIGS. 9 and 10 illustrate states in which the display device according to an embodiment is applied, respectively.

Referring to FIG. 9, the display device according to an embodiment may be applied to a vehicle. The vehicle may include display devices that are capable of providing driving information and/or entertainment-related information to a user. In an embodiment, for example, a first display device 1A corresponding to a room mirror, a second display device 1B configured to provide information about vehicle velocity, etc., and a third display device 1C configured to provide information about entertainments such as music or video may have the same structures as the display devices described above with reference to FIGS. 1A to 8B. In some embodiments, when the shape of the display device is not constant like the second display device 1B, the display devices according to the embodiments described with reference to FIGS. 1A to 8B may be fixedly mounted on the center fascia in a state of stretching or contracting in one direction. In an embodiment, for example, the display panel and the flexible film may be fixedly mounted on the center fascia in a state of stretching or contracting in one direction, and thus, the display area may have an asymmetrical shape in a vertical or horizontal direction. Although FIG. 9 illustrates that the display device according to the embodiment is applied to the vehicle, the disclosure is not limited thereto. The display devices according to the embodiments may be installed or installed in various types of structures, home appliances, and buildings.

In another embodiment, the display devices according to the embodiments described above with reference to FIGS. 1A to 8B may be a fourth display device 1D that is stretchable by external force such as joint motion. Although FIG. 10 illustrates that the display device according to the embodiment is a patch for the human body, in which extension and contraction are repeated, the disclosure is not limited thereto. A display device according to another embodiment may be implemented in various forms, for example, a display device that may be worn by various living bodies, such as humans or animals, or an electronic device that may be easy to carry.

In some embodiments, when the display panel stretches or contracts, the flexible film may be stretchable in one or more directions, and the strength for the flexible film may be maintained. However, such an effect is an example.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a display panel comprising light-emitting elements;
a circuit board; and
a flexible film electrically connected to the display panel and the circuit board, wherein the flexible film comprises:
a first portion in which a plurality of first pads electrically connected to the display panel is arranged;
a second portion in which a plurality of second pads electrically connected to the circuit board is arranged; and
a third portion between the first portion and the second portion,
wherein the first portion defines a first cutout pattern therein and between two first pads adjacent to each other among the plurality of first pads, and
the first cutout pattern extends to a first edge of the first portion in the flexible film.

2. The display device of claim 1, wherein an elongation rate of the first portion is greater than an elongation rate of the third portion.

3. The display device of claim 1, wherein the display panel comprises pads corresponding to the plurality of first pads of the flexible film, and
an elongation rate of one side-end portion of the display panel is equal to or greater than an elongation rate of the first portion.

4. The display device of claim 1, wherein one side-end portion of the display panel defines a cutout pattern therein and overlapping the first cutout pattern of the flexible film in a plan view, and
the cutout pattern of the display panel extends to an edge of the display panel.

5. The display device of claim 1, wherein an elongation rate of the second portion is greater than an elongation rate of the third portion.

6. The display device of claim 1, wherein the first cutout pattern comprises a first edge and a second edge between the two first pads adjacent to each other, and
the first edge and the second edge of the first cutout pattern are each uneven.

7. The display device of claim 1, wherein the second portion of the flexible film defines a second cutout pattern therein and between two second pads adjacent to each other among the plurality of second pads.

8. The display device of claim 7, wherein the second cutout pattern extends to a second edge of the second portion of the flexible film.

9. The display device of claim 1, further comprising:
an integrated circuit (IC) chip on the third portion of the flexible film;
a first line configured to electrically connect at least one of the plurality of first pads to the IC chip; and
a second line configured to electrically connect at least one of the plurality of second pads to the IC chip.

10. The display device of claim 9, wherein at least one of the first line or the second line comprises a portion extending in a serpentine type or defines a plurality of holes therein.

11. A display device comprising:
a display panel comprising light-emitting elements;
a circuit board; and
a flexible film electrically connected to the display panel and the circuit board,
wherein the flexible film comprises:
a first portion in which a plurality of first pads electrically connected to the display panel is arranged;
a second portion in which a plurality of second pads electrically connected to the circuit board is arranged; and
a third portion between the first portion and the second portion, and
the first portion defines a first groove pattern that is concave in a thickness direction of the flexible film and between two first pads adjacent to each other among the plurality of first pads.

12. The display device of claim 11, wherein an elongation rate of the first portion is greater than an elongation rate of the third portion.

13. The display device of claim 11, wherein the first groove pattern comprises a first portion having a first depth and a second portion having a second depth that is less than the first depth.

14. The display device of claim 11, wherein the display panel comprises pads corresponding to the plurality of first pads of the flexible film, and
an elongation rate of one side-end portion of the display panel is equal to or greater than an elongation rate of the first portion.

15. The display device of claim 11, wherein one side-end portion of the display panel defines a groove pattern therein and overlapping the first groove pattern of the flexible film in a plan view.

16. The display device of claim 15, wherein the first groove pattern of the flexible film extends to a first edge of the first portion of the flexible film, and
the groove pattern of the display panel extends to an edge of the display panel.

17. The display device of claim 11, wherein an elongation rate of the second portion of the flexible film is greater than an elongation rate of the third portion.

18. The display device of claim 11, wherein the second portion of the flexible film defines a second groove pattern therein and between two second pads adjacent to each other among the plurality of second pads and extending to a second edge of the second portion of the flexible film.

19. The display device of claim 11, further comprising:
an integrated circuit (IC) chip on the third portion of the flexible film;
a first line configured to electrically connect at least one of the plurality of first pads to the IC chip; and
a second line configured to electrically connect at least one of the plurality of second pads to the IC chip.

20. The display device of claim 19, wherein at least one of the first line or the second line comprises a portion extending in a serpentine type or defines a plurality of holes therein.
